(19) United States
(12) Patent Application Publication
(10) Pub. No.: US 2013/0126838 A1
(43) Pub. Date: May 23, 2013

(54) ORGANIC THIN FILMS, METHODS FOR FORMING THE SAME, AND ORGANIC THIN FILM TRANSISTORS INCLUDING THE SAME

(71) Applicant: Electronics and telecommunications research inst, Daejeon (KR)

(72) Inventors: Ye Sul JEONG, Gyeongsangbuk-do (KR); Kyu-Ha BAEK, Daejeon (KR)

(73) Assignee: ELECTRONICS AND TELECOMMUNICATIONS RESEARCH INSTITUTE, Daejeon (KR)

(21) Appl. No.: 13/684,275

(22) Filed: Nov. 23, 2012

(30) Foreign Application Priority Data
Nov. 23, 2011 (KR) 10-2011-0122816

(51) Int. Cl. H01L 51/05; B32B 3/30; B05D 5/00

(52) U.S. Cl. CPC H01L 51/0545; B05D 5/00; B32B 3/30
USPC 257/40; 427/265; 427/510; 428/161

(57) ABSTRACT

Provided is a method of forming an organic thin film including forming a first layer containing a first organic material on a substrate, performing a first imprint process on the first layer using a pattern mold, forming a second layer containing a second organic material on the first layer after the first imprint process, and performing a second imprint process on the second layer using a blanket mold.

### CROSS-REFERENCE TO RELATED APPLICATIONS

This U.S. non-provisional patent application claims priority under 35 U.S.C. §119 to Korean Patent Application No. 10-2011-0122816, filed on Nov. 23, 2011, in the Korean Intellectual Property Office, the entire contents of which are hereby incorporated by reference.

### BACKGROUND OF THE INVENTION

Embodiments of the inventive concepts relate to organic thin films, and in particular, an organic thin film formed by an imprint process, methods of forming the same, and transistors including the same.

Electronic devices may include a thin film made of organic or inorganic material. An organic film can be easily formed compared with an inorganic film, because it can be formed by, for example, a coating method. For example, the formation of the organic film does not need an expensive apparatus (e.g., high vacuum chamber) required for forming an inorganic layer, thereby reducing a process cost. In addition, the organic material has other technical advantages, such as, the easiness in controlling a planarization level and a film property. Accordingly, there have been extensive researches on the organic thin film, as alternative materials for replacing inorganic materials.

The organic thin film may be formed by spin coating, roll coating, dipping, screen printing, offset lithography printing, inkjet printing, flexo printing, and other printing methods. Recently, as the organic thin film is increasingly used for an organic dielectric layer, an organic electrode layer, and an organic active layer of an organic thin-film transistor, ongoing research is being done on a process technology for forming a uniformly thin organic thin film.

### SUMMARY

Example embodiments of the inventive concept provide organic thin films with a uniform thickness and methods of forming the same.

Other example embodiments of the inventive concept provide organic thin-film transistors with improved reliability.

According to example embodiments of the inventive concepts, a method of forming an organic thin film may include forming a first layer on a substrate to include a first organic material, performing a first imprint process on the first layer using a pattern mold, forming a second layer including a second organic material on the first layer, after the first imprint process, and performing a second imprint process on the second layer using a blanket mold.

In example embodiments, the performing of the first imprint process may include pressing the first layer with the pattern mold to form recess regions in the first layer, and curing the first layer provided with the recess region.

In example embodiments, the second layer may be formed to fill the recess regions.

In example embodiments, the pattern mold may include a plurality of patterned portions protruding from a surface of the pattern mold, and each of the patterned portions has the same height as that of the corresponding one of the recess regions.

In example embodiments, the curing of the first layer may be performed by irradiating an ultraviolet light onto the first layer or applying a thermal treatment to the first layer.

In example embodiments, the first and second organic materials may be the same material.

In example embodiments, the second imprint process may include pressing the second layer with the blanket mold to planarize a surface of the second layer, and curing the planarized second layer.

In example embodiments, the curing of the second layer may be performed by irradiating an ultraviolet light onto the second layer or applying a thermal treatment to the second layer.

In example embodiments, at least one of the first and second layers may further include a curing initiator.

According to example embodiments of the inventive concepts, an organic thin film may include a first layer including a plurality of recess regions spaced apart from each other, and a second layer provided on the first layer to include a plurality of protrusions filling the recess regions, respectively. Each of the recess regions has the same height as that of the corresponding one of the protrusions, and the first layer contains the same organic material as the second layer.

In example embodiments, the second layer may include a first surface arranged with the protrusions and a second surface opposite to the first surface, and the second surface of the second layer may be flat.

In example embodiments, surfaces of the protrusions of the second layer may be in contact with inner surfaces of the recess regions of the first layer, respectively.

According to example embodiments of the inventive concepts, an organic thin-film transistor may include a gate electrode disposed on a substrate, an organic insulating layer formed on the substrate to cover a gate electrode, an organic active layer disposed on the organic insulating layer, and first and second electrodes provided on the organic active layer and spaced apart from each other. The organic insulating layer may include first and second insulating layers sequentially stacked on the substrate, the first insulating layer including a plurality of recess regions spaced apart from each other, the second insulating layer including a plurality of protrusions filling the recess regions, respectively, each of the recess regions of the first insulating layer has the same height as that of the corresponding one of the protrusions of the second insulating layer, and the first insulating layer contains the same organic material as the second insulating layer.

In example embodiments, the second insulating layer may have a flat surface being in contact with the organic active layer.

In example embodiments, the organic active layer may include first and second semiconductor layers sequentially stacked on the organic insulating layer, the first semiconductor layer including a plurality of recess regions spaced apart from each other, and the second semiconductor layer including a plurality of protrusions filling the recess regions, respectively, each of the recess regions of the first semiconductor layer has the same height as that of the corresponding one of the protrusions of the second semiconductor layer, and the first semiconductor layer contains the same organic semiconductor material as the second semiconductor layer.

In example embodiments, the organic active layer may have a flat surface being in contact with the first electrode and the second electrode.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a flow chart illustrating a method of forming an organic thin film according to example embodiments of the inventive concept.

FIGS. 2A through 2E are sectional views illustrating a method of forming an organic thin film according to example embodiments of the inventive concept.

FIG. 3 is a sectional view illustrating an organic thin film according to example embodiments of the inventive concept

FIG. 4 is a sectional view illustrating an organic thin-film transistor provided with an organic thin film according to example embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

[Method of Forming an Organic Thin Film]

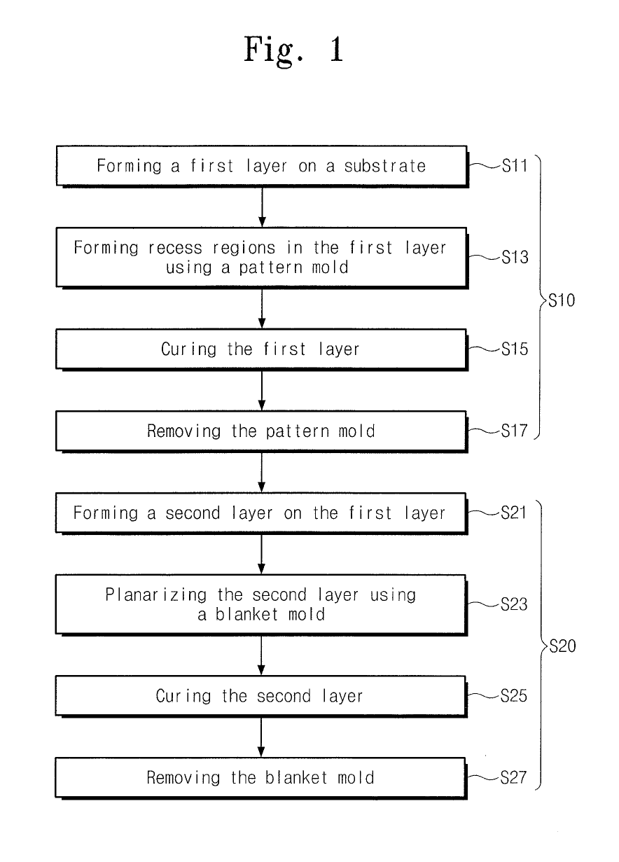

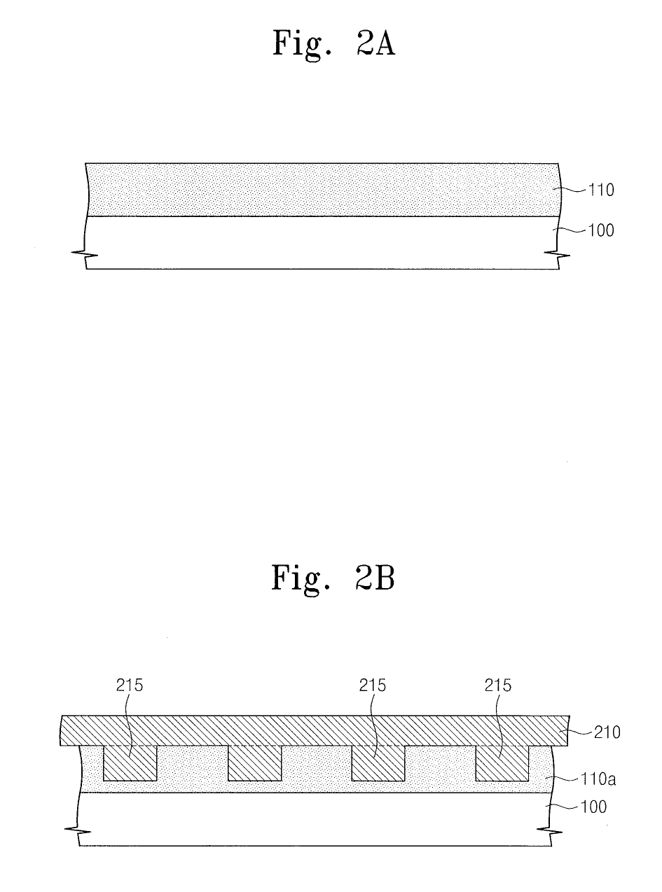

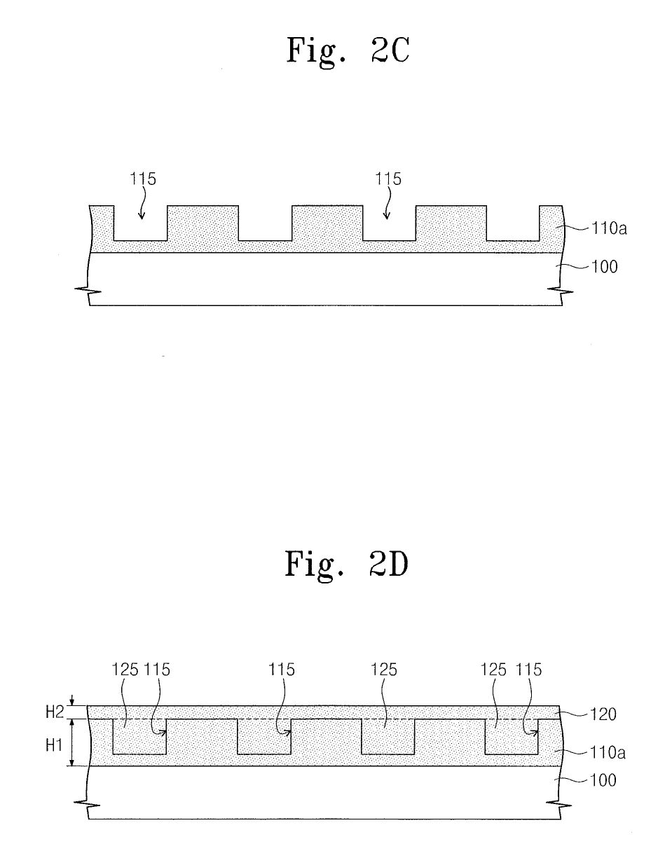

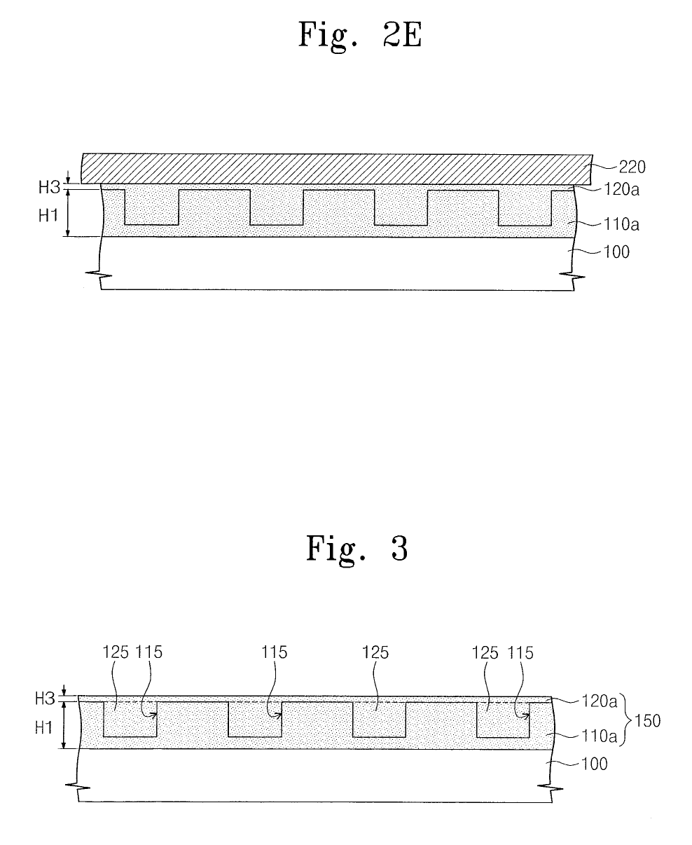

Hereinafter, a method of forming an organic thin film according to example embodiments of the inventive concept will be described with reference to the accompanying drawings. FIG. 1 is a flow chart illustrating a method of forming an organic thin film according to example embodiments of the inventive concept, and FIGS. 2A through 2E are sectional views illustrating a method of forming an organic thin film according to example embodiments of the inventive concept.

Referring to FIGS. 1 and 2A, a first layer 110 may be formed on a substrate 100 (in S11). The substrate 100 may be one of a glass substrate, a silicon substrate, a ceramic substrate, or a flexible substrate. In example embodiments, the substrate 100 may be a doped or undoped silicon substrate. In other example embodiments, the substrate 100 may be a flexible substrate including at least one of polyethylene terephthalate (PET), polyethelene naphthalate (PEN), polyether sulfone (PES), polyether imide, polyphenylene sulfide (PPS), polyallylate, polyimide, or polyacrylate.

The first layer 110 may be formed by coating a first organic resin on the substrate 100. In example embodiments, the first organic resin may include an organic dielectric material, on which an imprint process can be performed. For example, the first organic resin may include at least one of polyvinyl pyrrolidone (PVP), polystyrene, polyvinylphenol, polyphenol, polyacrylate, polymethyl methacrylate (PMMA), polyacrylamide, polyimide, polyacetal, polyvinyl acetate (PVA), or poly vinylidene, but example embodiments of the inventive concept will not be limited thereto. In other example embodiments, the first organic resin may include an organic semiconductor material. For example, the first organic resin may include at least one selected from the group consisting of pentacene, metal phthalocyanine, polythiophene, phenylenevinylene, phenylenetetracarboxylic dianydride, naphthalenetetracarboxylic dianydride, fluorophthalocyanine, and derivatives thereof.

In example embodiments, the first organic resin may further include a curing initiator. The curing initiator may be a photo-curable initiator or a heat-curable initiator. For example, the photo-curable initiator may be ammonium dichromate, and the heat-curable initiator may be a melamine resin.

Referring to FIGS. 1, 2B and 2C, a plurality of recess regions 115 may be formed in the first layer 110 using a pattern mold 210 (in S13). The pattern mold 210 may include a plurality of patterned portions 215, each of which may be shaped to have a protruding structure. The pattern mold 210 may be aligned in such a way that the patterned portions 215 face the first layer 110 provided on the substrate 100, and thereafter, the pattern mold 210 may be pressured to form the recess regions 115 in the first layer 110.

The first layer 110 provided with the recess region 115 may be cured to form a cured first layer 110a (in S15). The first layer 110 may be cured by irradiating an ultraviolet light onto the first layer 110 or applying heat to the first layer 110. In the case where the first organic resin includes the photo-curable initiator, the first layer 110 may be cured by irradiating an ultraviolet light thereon. In the case where the first organic resin includes the heat-curable initiator, the first layer 110 may be cured by applying heat thereto.

The pattern mold 210 may be removed from the cured first layer 110a (in S17). The recess regions 115 in the cured first layer 110a may be formed by a transcription of the patterned portions 215 of the pattern mold 210 into the cured first layer 110a. In other words, a depth of the recess regions 115 may be substantially equivalent to a height of the pattern portion 215 of the pattern mold 210. In example embodiments, a bottom surface of the recess regions 115 may be delimited by a portion of the cured first layer 110a. For example, the recess regions 115 may have a depth smaller than the maximal thickness of the cured first layer 110a.

Steps of forming the first layer 110 (in S11), forming the recess region 115 in the first layer 110 using the pattern mold 210 (in S13), curing the first layer 110a (in S15), and removing the pattern mold 210 (in S17) may constitute a first imprint process (in S10). As the result of the first imprint process (in S10), the cured first layer 110a may be formed on the substrate 100 to have the recess regions 115.

Referring to FIGS. 1 and 2D, a second layer 120 may be formed on the substrate 100 (in S21). The second layer 120 may be formed by coating a second organic resin on the substrate 100. The second layer 120 may be formed to fill the recess regions 115 of the cured first layer 110. For example, the second layer 120 may include protrusions 125 filling the recess regions 115. In example embodiments, the cured first layer 110a may be formed to have a first thickness H1, and the second layer 120 may be formed to have a second thickness H2. The first thickness H1 may be a thickness of a portion of the cured first layer 110a positioned between adjacent ones of the recess regions 115, and the second thickness H2 may be a thickness of a portion of the second layer 120 positioned between adjacent ones of the protrusions 125.

In example embodiments, the second organic resin may include an organic dielectric material, to which an imprint process can be applied. For example, the second organic resin may include at least one of polyvinyl pyrrolidone (PVP), polystyrene, polyvinylphenol, polyphenol, polyacrylate, polymethyl methacrylate (PMMA), polyacrylamide, polyimide, polyacetal, polyvinyl acetate (PVA), or poly vinylidene, but example embodiments of the inventive concepts may not be limited thereto. In other embodiments, the second organic resin may include an organic semiconductor material. For example, the second organic resin may include at least one selected from the group consisting of pentacene, metal phthalocyanine, polythiophene, phenylenevinylene, phenylenetetracarboxylic dianydride, naphthalenetetracarboxylic dianydride, fluorophthalocyanine, and derivatives thereof.

In example embodiments, the first organic resin and the second organic resin may include the same organic material.

In example embodiments, the second organic resin may further include a curing initiator. The curing initiator may be a photo-curable initiator or a heat-curable initiator. For example, the photo-curable initiator may be ammonium dichromate, and the heat-curable initiator may be a melamine resin.

Referring to FIGS. 1 and 2E, the second layer 120 may be planarized using a blanket mold 220 (in S23). The blanket mold 220 may have a flat surface. For example, the blanket mold 220 may be aligned in such a way that the flat surface of the blanket mold 220 faces the second layer 120, and be pressured to planarize the second layer 120.

The second layer 120 may be cured (in S25). The second layer 120 may be cured by irradiating an ultraviolet light onto the second layer 120 or applying heat to the second layer 120. In the case where the second organic resin includes the photo-curable initiator, the second layer 120 may be cured by irradiating an ultraviolet light thereon. In the case where the second organic resin includes the heat-curable initiator, the second layer 120 may be cured by applying heat thereto.

As the result of the pressing process, a planarized second layer 120a may have a thickness smaller than that of the second layer 120. For example, a portion of the planarized second layer 120a between the protrusions 125 of the planarized second layer 120a may have a third thickness H3, which may be, for example, smaller than the second thickness H2.

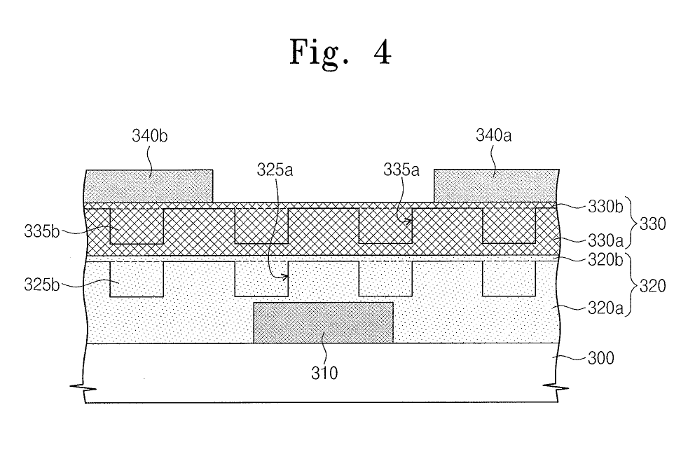

Steps of forming the second layer 120 (in S21), planarizing the second layer 120 using the blanket mold 220 (in S23), curing the second layer 120 (in S25), and removing the blanket mold 220 (in S27) may constitute a second imprint process (in S20). By performing the first and second imprint processes (in S10 and S20), as shown in FIG. 3, an organic thin film 150 may be formed on the substrate 100 to include the cured first layer 110a and the planarized second layer 120a.

According to example embodiments of the inventive concept, the first and second imprint processes (in S10 and S20) may be performed to form the organic thin film 150 on the substrate 100. As the result of the first imprint process (in S10), the first layer 110 may be formed on the substrate 100 to have the recess regions 115, and as the result of the second imprint process, the second layer 120 may be formed on the substrate 100 to fill the recess regions 115 and have a planarized top surface. Accordingly, the organic thin film 150 may be formed to have a uniform thickness. If the organic thin film is formed using only a spin coating or spraying process, it may be hard to control a thickness of the organic thin film or improve thickness uniformity of the organic thin film. However, according to example embodiments of the inventive concept, since the organic thin film is formed using the first and second imprint processes (in S10 and S20), it is possible to improve the thickness uniformity of the organic thin film or easily form an organic thin film with a desired thickness. As a result, electronic devices provided with the organic thin film 150 can have improved characteristics.

In addition, according to example embodiments of the inventive concept, the organic thin film 150 may have a surface planarized by the second imprint process (in S20). If the second imprint process (in S20) is omitted, a thermal treatment process and a surface planarizing process should be additionally performed on a surface of the organic thin film, after forming the organic thin film. However, according to example embodiments of the inventive concept, since the surface of the organic thin film 150 is planarized by the second imprint process (in S20), the thermal treatment process or the surface planarizing process can be omitted. This enables to simplify a process of fabricating the organic thin film 150 and reduce a fabrication cost thereof.

[Organic Thin Film]

FIG. 3 is a sectional view illustrating an organic thin film according to example embodiments of the inventive concept.

Referring to FIG. 3, the organic thin film 150 may be disposed on the substrate 100. The substrate 100 may be one of a glass substrate, a silicon substrate, a ceramic substrate, or a flexible substrate. For example, the substrate 100 may be a doped or undoped silicon substrate. In other example embodiments, the substrate 100 may be a flexible substrate including at least one of polyethylene terephthalate (PET), polyethelene naphthalate (PEN), polyether sulfone (PES), polyether imide, polyphenylene sulfide (PPS), polyallylate, polyimide, or polyacrylate.

The organic thin film 150 may include the first layer 110a and the second layer 120a. The first layer 110a and the second layer 120a may include an organic dielectric material. For example, the first layer 110a and the second layer 120a may include at least one of polyvinyl pyrrolidone (PVP), polystyrene, polyvinylphenol, polyphenol, polyacrylate, polymethyl methacrylate (PMMA), polyacrylamide, polyimide, polyacetal, polyvinyl acetate (PVA), or poly vinylidene, but example embodiments of the inventive concepts may not be limited thereto. In other embodiments, the first layer 110a and the second layer 120a may include an organic semiconductor material. For example, at least one of the first and second layers 110a and 120a may include at least one selected from the group consisting of pentacene, metal phthalocyanine, polythiophene, phenylenevinylene, phenylenetetracarboxylic dianydride, naphthalenetetracarboxylic dianydride, fluorophthalocyanine, and derivatives thereof.

In example embodiments, the first layer 110a and the second layer 120a may include the same organic material.

The first layer 110a may include a plurality of the recess regions 115 spaced apart from each other. The recess regions 115 may be formed not to expose the substrate 100. In other words, bottom surfaces of the recess regions 115 may be delimited by the first layer 110a. In example embodiments, a portion of the first layer 110a positioned between the recess regions 115 may have the first thickness H1.

The second layer 120a may include a plurality of the protrusions 125 spaced apart from each other. Each of the protrusions 125 of the second layer 120a may be disposed in the corresponding one of the recess regions 115 of the first layer 110. For example, each of the protrusions 125 of the second layer 120a may be shaped to have a structure completely filling the corresponding one of the recess regions 115 of the first layer 110. The second layer 120a may have a flat surface. The flat surface of the second layer 120a may be positioned opposite to the protrusions 125.

The portion of the second layer 120a positioned between protrusions 125 may have the third thickness H3. A thickness of the organic thin film 150 may be a sum of the first thickness H1 and the third thickness H3.

[Organic Thin-Film Transistor]

Hereinafter, an organic thin-film transistor, in which an organic thin film according to example embodiments of the inventive concept is provided, will be described with reference to the accompanying drawings. FIG. 4 is a sectional view illustrating an organic thin-film transistor provided with an organic thin film according to example embodiments of the inventive concept.

Referring to FIG. 4, a gate electrode 310 may be disposed on a substrate 300. The substrate 300 may be one of a glass substrate, a silicon substrate, a ceramic substrate, or a flexible substrate.

In example embodiments, the gate electrode 310 may include at least one of doped polysilicon, metals (e.g., aluminum, gold, chromium, or indium tin oxide), or conductive polymers (e.g., doped polyaniline, polystyrene sulfonate, doped poly(3,4-ethylene dioxythiophene) (PSS-PEDOT), or a conductive ink/paste made of carbon black or graphite).

An organic insulating layer 320 may be provided on the substrate 300. The organic insulating layer 320 may be formed using the method previously described with reference to FIGS. 1 and 2A through 2E. The organic insulating layer 320 may include a first insulating layer 320a and a second insulating layer 320b. The first insulating layer 320a may include a plurality of recess regions 325a spaced apart from each other. The recess regions 325a may be formed not to expose the substrate 300. For example, bottom surfaces of the recess regions 325a may be delimited by the first insulating layer 320a.

The second insulating layer 320b may include a plurality of protrusions 325b spaced apart from each other. Each of the protrusions 325b of the second insulating layer 320b may be disposed in the corresponding one of the recess regions 325a of the first insulating layer 320a. For example, each of the protrusions 325b of the second insulating layer 320b may be shaped to have a structure completely filling the corresponding one of the recess regions 325a of the first insulating layer 320a. The second insulating layer 320b may have a flat surface. The flat surface of the second insulating layer 320b may be positioned opposite to the protrusions 325b.

In example embodiments, the protrusions 325b may have surfaces, which may be in direct contact with inner surfaces of the recess regions 325a, respectively.

The first insulating layer 320a and the second insulating layer 320b may include an organic insulating material. For example, the first layer and the second layer may include at least one of polyvinyl pyrrolidone (PVP), polystyrene, polyvinylphenol, polyphenol, polyacrylate, polymethyl methacrylate (PMMA), polyacrylamide, polyimide, polyacetal, polyvinyl acetate (PVA), or poly vinylidene. In example embodiments, the first insulating layer 320a and the second insulating layer 320b may include the same organic material.

An organic active layer 330 may be provided on the organic insulating layer 320. In example embodiments, the organic active layer 330 may be formed using the method previously described with reference to FIGS. 1 and 2A through 2E. The organic active layer 330 may include a first semiconductor layer 330a and a second semiconductor layer 330b. The first semiconductor layer 330a may include a plurality of recess regions 335a spaced apart from each other. The recess regions 335a may be formed not to expose the organic insulating layer 320. For example, bottom surfaces of the recess regions 335a may be delimited by the first semiconductor layer 330a.

The second semiconductor layer 330b may include a plurality of protrusions 335b spaced apart from each other. Each of the protrusions 335b of the second semiconductor layer 330b may be disposed in the corresponding one of the recess regions 335a of the first semiconductor layer 330a. For example, each the protrusions 335b of the second semiconductor layer 330b may be shaped to have a structure completely filling the corresponding one of the recess regions 335a of the first semiconductor layer 330a. The second semiconductor layer 330b may have a flat surface. The flat surface of the second semiconductor layer 330b may be positioned opposite to the protrusions 335b.

In example embodiments, the protrusions 335b may have surfaces, which may be in direct contact with inner surfaces of the recess regions 335a, respectively.

The first semiconductor layer 330a and the second semiconductor layer 330b may include an organic dielectric material. Alternatively, the first semiconductor layer 330a and the second semiconductor layer 330b may include an organic semiconductor material. For example, at least one of the first and second semiconductor layers 330a and 330b may include at least one selected from the group consisting of pentacene, metal phthalocyanine, polythiophene, phenylenevinylene, phenylenetetracarboxylic dianydride, naphthalenetetracarboxylic dianydride, fluorophthalocyanine, and derivatives thereof.

A first electrode 340a and a second electrode 340b may be provided on the organic active layer 330. One of the first and second electrodes 340a and 340b may serve as a source electrode, and the other may serve as a drain electrode. The first electrode 340a and the second electrode 340b may include at least one of doped polysilicon, metals (e.g., aluminum, gold, chromium, or indium tin oxide), or conductive polymers (e.g., doped polyaniline, polystyrene sulfonate, doped poly(3,4-ethylene dioxythiophene) (PSS-PEDOT), or a conductive ink/paste made of carbon black or graphite).

According to example embodiments of the inventive concepts, the organic insulating layer 320 and the organic active layer 330 of an organic thin-film transistor may be formed using the method of forming an organic thin film described with reference to FIGS. 1 and 2A through 2E. For example, the organic insulating layer 320 and the organic active layer 330 may be formed through the first and second imprint processes (in S10 and S20) previously described with reference to FIG. 1. Accordingly, the organic insulating layer 320 and the organic active layer 330 may be formed to have a uniform thickness. If the organic insulating layer and the organic active layer are formed using only a spin coating or spraying process, it may be hard to control thicknesses of the organic insulating layer and the organic active layer or improve thickness uniformity of the organic insulating layer and the organic active layer. However, according to example embodiments of the inventive concept, since the organic insulating layer 320 and the organic active layer 330 are formed using the first and second imprint processes (in S10 and S20), it is possible to improve the thickness uniformity of the organic insulating layer 320 and the organic active layer 330 or easily form the organic insulating layer 320 and the organic active layer 330 with desired thicknesses. As a result, organic thin-film transistors provided with the organic insulating layer 320 and organic active layer 330 can have improved electric characteristics.

In addition, according to example embodiments of the inventive concept, the organic insulating layer 320 and the organic active layer 330 may have surfaces planarized by the second imprint process (in S20). Accordingly, the organic insulating layer 320 and the organic active layer 330 can be planarized without an additional thermal treatment or surface planarizing process. This enables to simplify a process of fabricating the organic thin-film transistor and reduce a fabrication cost thereof.

According to example embodiments of the inventive concept, an organic thin film may include a first layer and a second layer. Here, the first layer may be formed using a first imprint process to have recess regions, and the second layer may be formed using a second imprint process to have protrusions filling the recess regions, respectively. As a result, the organic thin film can be formed to have a uniform thickness. In addition, the formation of the first and second layers enables to control easily a thickness of the organic thin film. As a result, the use of the organic thin film according to example embodiments of the inventive concept enables to improve characteristics of electronic devices.

In addition, according to example embodiments of the inventive concept, a surface of the organic thin film may be planarized by the second imprint process. Accordingly, the organic thin film can be planarized without an additional thermal treatment or surface planarizing process. This enables to simplify a process of forming the organic thin film and reduce a fabrication cost thereof.

While example embodiments of the inventive concepts have been particularly shown and described, it will be understood by one of ordinary skill in the art that variations in form and detail may be made therein without departing from the spirit and scope of the attached claims.

What is claimed is:

1. A method of forming an organic thin film, comprising:
forming a first layer containing a first organic material, on a substrate;
performing a first imprint process on the first layer using a pattern mold;
forming a second layer containing a second organic material on the first layer, after the first imprint process; and
performing a second imprint process on the second layer using a blanket mold.

2. The method of claim 1, wherein the performing of the first imprint process comprises:
pressing the first layer with the pattern mold to form recess regions in the first layer; and
curing the first layer provided with the recess region.

3. The method of claim 2, wherein the second layer is formed to fill the recess regions.

4. The method of claim 2, wherein the pattern mold comprises a plurality of patterned portions protruding from a surface of the pattern mold, and
each of the patterned portions has the same height as that of the corresponding one of the recess regions.

5. The method of claim 2, wherein the curing of the first layer is performed by irradiating an ultraviolet light onto the first layer or applying a thermal treatment to the first layer.

6. The method of claim 1, wherein the first and second organic materials are the same material.

7. The method of claim 1, wherein the second imprint process comprises:
pressing the second layer with the blanket mold to planarize a surface of the second layer; and
curing the planarized second layer.

8. The method of claim 7, wherein the curing of the second layer is performed by irradiating an ultraviolet light onto the second layer or applying a thermal treatment to the second layer.

9. The method of claim 1, wherein at least one of the first and second layers further comprises a curing initiator.

10. An organic thin film, comprising:
a first layer including a plurality of recess regions spaced apart from each other; and
a second layer provided on the first layer to include a plurality of protrusions filling the recess regions, respectively,
wherein each of the recess regions has the same height as that of the corresponding one of the protrusions, and
the first layer contains the same organic material as the second layer.

11. The organic thin film of claim 10, wherein the second layer comprises a first surface arranged with the protrusions and a second surface opposite to the first surface, and
the second surface of the second layer is flat.

12. The organic thin film of claim 10, wherein surfaces of the protrusions of the second layer are in contact with inner surfaces of the recess regions of the first layer, respectively.

13. An organic thin-film transistor, comprising:
a gate electrode disposed on a substrate;
an organic insulating layer formed on the substrate to cover a gate electrode;
an organic active layer disposed on the organic insulating layer; and
first and second electrodes provided on the organic active layer and spaced apart from each other,
wherein the organic insulating layer comprises first and second insulating layers sequentially stacked on the substrate, the first insulating layer including a plurality of recess regions spaced apart from each other, the second insulating layer including a plurality of protrusions filling the recess regions, respectively,
each of the recess regions of the first insulating layer has the same height as that of the corresponding one of the protrusions of the second insulating layer, and
the first insulating layer contains the same organic material as the second insulating layer.

14. The transistor of claim 13, wherein the second insulating layer has a flat surface being in contact with the organic active layer.

15. The transistor of claim 13, wherein the organic active layer comprises first and second semiconductor layers sequentially stacked on the organic insulating layer, the first semiconductor layer including a plurality of recess regions spaced apart from each other, and the second semiconductor layer including a plurality of protrusions filling the recess regions, respectively,
each of the recess regions of the first semiconductor layer has the same height as that of the corresponding one of the protrusions of the second semiconductor layer, and
the first semiconductor layer contains the same organic semiconductor material as the second semiconductor layer.

16. The transistor of claim 15, wherein the organic active layer has a flat surface being in contact with the first electrode and the second electrode.
